(19) United States
(12) Patent Application Publication
(10) Pub. No.: US 2022/0216049 A1
(43) Pub. Date: Jul. 7, 2022

(54) METHOD FOR FORMING SEMICONDUCTOR STRUCTURE

(71) Applicants: Semiconductor Manufacturing International (Beijing) Corporation, Beijing (CN); Semiconductor Manufacturing International (Shanghai) Corporation, BeijingShanghai (CN)

(72) Inventors: Lanfang SHI, SHANGHAI (CN); Lu GAN, SHANGHAI (CN); WeiWei WU, SHANGHAI (CN); Wenguang ZHANG, SHANGHAI (CN); Chunsheng ZHENG, SHANGHAI (CN)

(73) Assignees: Semiconductor Manufacturing International (Beijing) Corporation, Beijing (CN); Semiconductor Manufacturing International (Shanghai) Corporation, BeijingShanghai (CN)

(21) Appl. No.: 17/543,191

(22) Filed: Dec. 6, 2021

(30) Foreign Application Priority Data
Jan. 6, 2021 (CN) 202110015122.8

(51) Int. Cl. H01L 21/02

(52) U.S. Cl. CPC H01L 21/0217; H01L 21/0228; H01L 21/02274

(57) ABSTRACT

A method for forming a semiconductor structure is provided. In one form, a method includes: providing a to-be-processed base structure, where the to-be-processed base structure includes a base layer and pattern structures protruding from the base layer, and a surface of the base structure has adsorption groups; performing plasma treatment on the surface of the base structure by using a reaction gas, where the reaction gas chemically reacts with the adsorption group to cause quantities of precursor adsorption nucleation points on the surface of the base structure to tend to be same; and after the plasma treatment, forming, by using an atomic layer deposition (ALD) process, a target layer conformally covering the surface of the base structure. The plasma treatment is performed on the surface of the base structure, so that the quantities of the precursor adsorption nucleation on top surfaces and sidewalls of the pattern structures and on the surface of the base layer are the same, achieving the modification to the surface of the base structure. Therefore, the thickness uniformity of the target layer is improved, thereby enhancing the performance of a semiconductor.

### RELATED APPLICATIONS

The present application claims priority to Chinese Patent Appln. No. 202110015122.8, filed Jan. 6, 2021, the entire disclosure of each of which are hereby incorporated by reference.

### TECHNICAL FIELD

Embodiments and implementations of the present disclosure relate to the field of semiconductor manufacturing, and in particular, to a method for forming a semiconductor structure.

### BACKGROUND

An atomic layer deposition (ALD) process generally provides the ability to deposit a plurality of successive monoatomic layers on a base in a deposition chamber maintained at a negative pressure (a pressure below an atmospheric pressure). The process normally includes a plurality of deposition sub-steps. The deposition sub-steps may include: introducing a first reaction precursor into a deposition chamber, where the first reaction precursor is adsorbed onto a surface of the base; stopping introduction of the first reaction precursor into the deposition chamber to cause an inert purge gas to flow through the deposition chamber, so as to remove, from the deposition chamber, the remaining first reaction precursor that is not adsorbed onto the base; introducing a second reaction precursor into the deposition chamber, where the second reaction precursor reacts with the first reaction precursor adsorbed onto the surface of the base; and stopping introduction of the second reaction precursor into the deposition chamber to cause the inert purge gas to flow through the deposition chamber, so as to discharge, from the deposition chamber, a by-product formed after the second reaction precursor reacts with the first reaction precursor.

In an existing semiconductor manufacturing process, with the further development of the process for manufacturing semiconductor devices, the feature size of the device becomes increasingly smaller. The ALD process is mainly applicable to holes, openings, or grooves that have relatively small line widths and relatively large depth-to-width ratios.

### SUMMARY

A solution to address the above-described problems is presented in embodiments and implementations of the present disclosure that provide a method for forming a semiconductor structure, to enhance the performance of a semiconductor structure.

To address the foregoing problem, one form of the present disclosure provides a method for forming a semiconductor structure. The method may include: providing a to-be-processed base structure, where the to-be-processed base structure includes a base layer and pattern structures protruding from the base layer, and a surface of the base structure has adsorption groups; performing plasma treatment on the surface of the base structure using a reaction gas, where the reaction gas chemically reacts with the adsorption group to cause quantities of precursor adsorption nucleation points on the surface of the base structure to tend to be same; and after the plasma treatment, forming, using an atomic layer deposition (ALD) process, a target layer conformally covering the surface of the base structure.

In some implementations, the reaction gas includes O₂, H₂, or a gas containing N and H.

In some implementations, the gas containing N and H includes a gas mixture of N₂ and H₂ or NH₃. In some implementations, the adsorption group includes hydroxyl or amino.

In some implementations, the pattern structures and the base layer are made of different materials.

In some implementations, the base layer includes a plurality of regions. The pattern structures are respectively located on the base layers in the plurality of regions, where concentrations of doped ions in the pattern structures in the plurality of regions are different, or types of doped ions in the pattern structures in the plurality of regions are different, or the pattern structures in the plurality of regions are made of different materials.

In some implementations, the base layer is a substrate, each pattern structure is a gate structure, and the target layer is a spacer material layer, or a to-be-connected structure is formed in the base layer, the pattern structure is a dielectric layer, adjacent dielectric layers form a conductive opening, the to-be-connected structure is exposed from a bottom of the conductive opening, and the target layer is a sidewall protection material layer.

In some implementations, the plasma treatment includes the following parameters: the reaction gas is O₂; a process duration being in a range of 5 s to 600 s; a chamber pressure is in a range of 100 mtorr to 30 torr; a gas flow rate of the reaction gas is in a range of 1 sccm to 90000 sccm; a radio-frequency power is in a range of 50 W to 2000 W; and a process temperature is in a range of 50° C. to 500° C.

In some implementations, materials of the pattern structures include silicon oxide, silicon nitride, and a silicon material. In some implementations, a material of the target layer includes silicon nitride.

In some implementations, the ALD process includes a plasma enhanced ALD process. Compared with the prior art, the technical solutions of the embodiments of the present disclosure have the following advantages:

In solutions disclosed in embodiments and implementations of the present disclosure, the to-be-processed base structure includes a base layer and pattern structures protruding from the base layer. A surface of the base structure has adsorption groups. Then, plasma treatment is performed on the surface of the base structure using a reaction gas. The reaction gas chemically reacts with the adsorption group to cause the quantities of precursor adsorption nucleation points on the surface of the base structure to tend to be the same. Then, the ALD process is used to form a target layer conformally covering the surface of the base structure. Compared with solutions that the target layer conformally covering the surface of the base structure is formed on the surface of the base structure by directly using the ALD process without performing the plasma treatment on the surface of the base structure, in embodiments and implementations of the present disclosure, the plasma treatment is performed on the surface of the base structure, so that quantities of the precursor adsorption nucleation points on top surfaces and sidewalls of the pattern structures and on the surface of the base layer tend to be same. In this way, the modification to the surface of the base structure is implemented. Since the precursor adsorption nucleation points are used for adsorbing reaction precursors used in the ALD process, a uniform adsorption environment is provided for the reaction precursors. Correspondingly, the thickness uniformity of the target layer is improved, thereby enhancing the performance of a semiconductor.

### BRIEF DESCRIPTION OF THE DRAWINGS

FIG. 1 to FIG. 3 are schematic structural diagrams corresponding to steps in a method for forming a semiconductor structure.

FIG. 4 to FIG. 7 are schematic structural diagrams corresponding to steps in one form of a method for forming a semiconductor structure according to the present disclosure.

FIG. 8 is a schematic diagram corresponding to another form of a method for forming a semiconductor structure according to the present disclosure.

FIG. 9 is a schematic diagram corresponding to yet another form of a method for forming a semiconductor structure according to the present disclosure.

### DETAILED DESCRIPTION

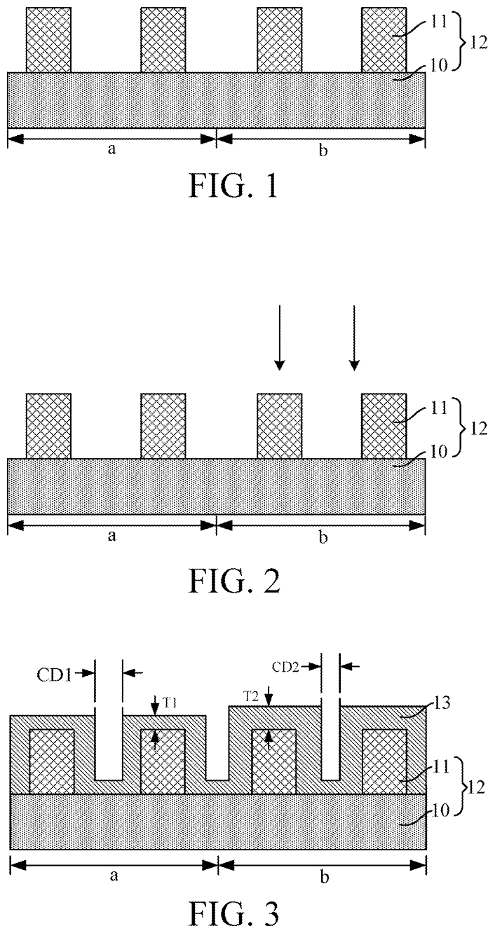

A performance of current semiconductor structures may still be improved. Reasons why the performance of a semiconductor structure may still to be improved are analyzed below in combination with a method for forming a semiconductor structure. FIG. 1 to FIG. 3 are schematic structural diagrams corresponding to steps in a method for forming a semiconductor structure.

Referring to FIG. 1, a to-be-processed base structure 12 is provided. The to-be-processed base structure 12 includes a base layer 10 and pattern structures 11 protruding from the base layer 10. The base structure 12 includes a first device region a and a second device region b.

Referring to FIG. 2, ion doping treatment is performed on the pattern structures 11 in the second device region b.

Referring to FIG. 3, after the ion doping treatment is performed, a target layer 13 conformally covering a surface of the base structure 12 is formed using an atomic layer deposition (ALD) process.

It is found through research that, after the ion doping treatment is performed on the pattern structures 11 in the second device region b, changes in adsorption groups on a surface of the pattern structures 11 in the second device region b are easily caused. Therefore, a difference is generated between the adsorption groups and adsorption groups on the surface of the pattern structures 11 in the first device region a. Correspondingly, during the formation of the target layer 13 on the surface of the base structure 12, due to the influence of the adsorption groups on the surface of the pattern structures 11, a thickness T1 of the target layer 13 formed on the surface of the pattern structures 11 in the first device region a is not equal to a thickness T2 of the target layer 13 formed on the surface of the pattern structures 11 in the second device region b. In addition, a direction perpendicular to an extending direction of the pattern structures 11 is used as a transverse direction. A transverse distance CD1 between adjacent target layers 13 in the first device region a that are located on sidewalls of the pattern structures 11 is not equal to a transverse distance CD2 between adjacent target layers 13 in the second device region b that are located on sidewalls of the pattern structures 11 either. Moreover, the adsorption groups on the surface of the base layer 10 and the surfaces of the pattern structures 11 are also prone to differences. As a result, a thickness of the target layer 13 on the surface of the pattern structures 11 is not equal to a thickness of the target layer 13 on the surface of the base layer 10, resulting in poor thickness uniformity of the target layer 13 and poor transverse distance uniformity between adjacent target layers 13. Therefore, the above problems easily cause the performance of the semiconductor structure to decrease.

To address these technical problems, one form of the present disclosure provides a method for manufacturing a semiconductor structure. The form of the method includes: providing a to-be-processed base structure, where the to-be-processed base structure includes a base layer and pattern structures protruding from the base layer, and a surface of the base structure has adsorption groups; performing plasma treatment on the surface of the base structure using a reaction gas, where the reaction gas chemically reacts with the adsorption group to cause quantities of precursor adsorption nucleation points on the surface of the base structure to tend to be same; and after the plasma treatment, forming, using an atomic layer deposition (ALD) process, a target layer conformally covering the surface of the base structure.

In embodiments and implementations of the present disclosure, the to-be-processed base structure includes the base layer and the pattern structures protruding from the base layer. The surface of the base structure has adsorption groups. Then, plasma treatment is performed on the surface of the base structure using a reaction gas. The reaction gas chemically reacts with the adsorption group to cause the quantities of precursor adsorption nucleation points on the surface of the base structure to tend to be the same. Then, the ALD process is used to form a target layer conformally covering the surface of the base structure, and thicknesses of the target layer are consistent. Compared with the solution that the target layer conformally covering the surface of the base structure is formed on the surface of the base structure by directly using the ALD process without performing the plasma treatment on the surface of the base structure, in embodiments and implementations of the present disclosure, the plasma treatment is performed on the surface of the base structure, so that quantities of the precursor adsorption nucleation on top surfaces and sidewalls of the pattern structures and on the surface of the base layer tend to be same. In this way, the modification to the surface of the base structure is implemented. Since the precursor adsorption nucleation points are used for adsorbing reaction precursors used in the ALD process, a uniform adsorption environment is provided for the reaction precursors. Correspondingly, the thickness uniformity of the target layer is improved, thereby enhancing the performance of a semiconductor.

To make the foregoing objectives, features, and advantages of embodiments and implementations of the present disclosure more apparent and easier to understand, specific embodiments and implementations of the present disclosure are described in detail below with reference to the accompanying drawings.

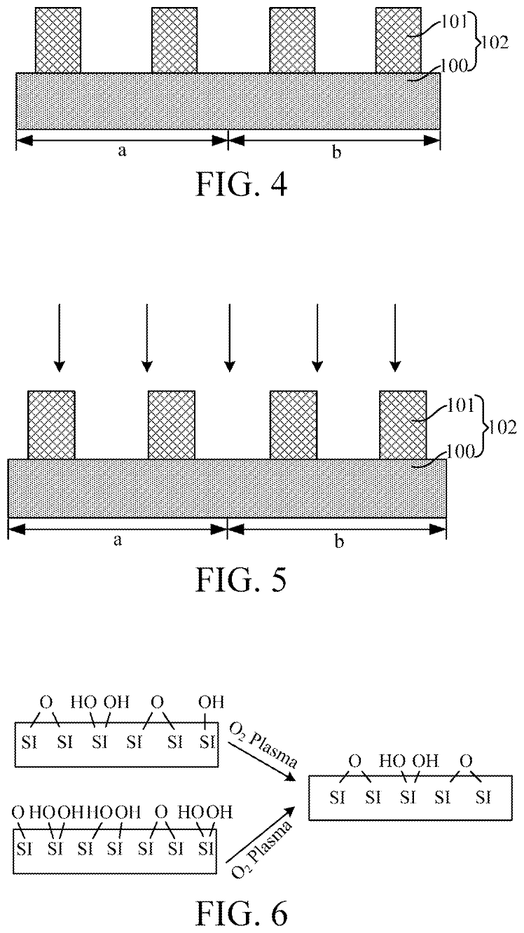

FIG. 4 to FIG. 7 are schematic diagrams corresponding to steps in one form of a method for forming a semiconductor structure according to the present disclosure.

Referring to FIG. 4, a to-be-processed base structure 102 is provided. The to-be-processed base structure 102 includes a base layer 100 and pattern structures 101 protruding from the base layer 100. A surface of the base structure 102 has adsorption groups.

The base structure 102 provides a process platform for the subsequent formation of a target layer.

The target layer conformally covering the surface of the base structure 102 is subsequently formed. Thus, the surface of the base structure 102 provides a deposition environment for the target layer.

In some implementations, the surface of the base structure 102 has the adsorption group.

As an example, the adsorption group includes hydroxyl (OH—). In other implementations, the adsorption group may alternatively be amino (NH— or NH₂).

It is to be noted that, with the influence of a manufacturing process, each surface of the base structure 102 has different quantities of adsorption groups.

For example, the base structure 102 includes a plurality of film layers made of different materials. Alternatively, each region in the base structure 102 undergoes different process conditions. Alternatively, the process of forming the base structure 102 may be affected by the process variation. The adsorption groups on the surface of the base structure 102 affect the deposition environment for the subsequent formation of the target layer.

In some implementations, the pattern structures 101 and the base layer 100 are made of different materials. Therefore, the quantity of the adsorption groups on the surface of the base layer 100 is different from the quantity of the adsorption groups on the surface of the pattern structures 101.

In some implementations, materials of the pattern structures 101 include silicon oxide, silicon nitride, or silicon. The silicon material may include polysilicon or amorphous silicon.

Specifically, the base layer 100 is a substrate. The pattern structure 101 is a gate structure.

The substrate is made of silicon. In other implementations, a material of the substrate may also be germanium, silicon carbide, gallium arsenide, or indium gallium, and the substrate can also be a silicon substrate on an insulator or a germanium substrate on an insulator.

The gate structure is made of polysilicon.

In some implementations, the base layer 100 includes a plurality of regions (not shown). As an example, the plurality of regions include a first region a and a second region b.

In some implementations, the pattern structures 101 are respectively located on the base layer 100 of the plurality of regions. Concentrations of doped ions in the pattern structures 101 of the plurality of regions (that is, the first region a and the second region b) are different.

The pattern structures 101 of the first region a and the second region b are made of the same material, but concentrations of doped ions in the pattern structures 101 of the first region a and the second region b are different. This causes different quantities of adsorption groups to be formed on the surfaces of the pattern structures 101 of the first region a and the second region b.

It is to be noted that, concentrations of doped ions in the pattern structures 101 of the first region a and the second region b are set to be different, which is mainly to meet some specific requirements of a semiconductor structure or the purpose in performance.

As an example, the pattern structures 101 in the second region b are doped with ions, and the pattern structures 101 in the first region a are not doped with the ions.

After ion doping is performed on the pattern structures 101 in the second region b, the quantity of the adsorption groups on the surfaces of the pattern structures 101 in the second region b is changed.

In some other implementations, the pattern structures in the plurality of regions are made of a same material. Doped ion types in the pattern structures in the plurality of regions are different. For example, the pattern structures in the first region are doped with N-type ions, and the pattern structures in the second region are doped with P-type ions.

In still some other implementations, the pattern structures in the plurality of regions are made of different materials.

In other implementations, the pattern structures in the plurality of regions are made of the same material, doped ions are the same, or none of the pattern structures are doped with ions. In this case, the influence of the process variation may also cause the surfaces of the pattern structures in the plurality of regions to have different quantities of adsorption groups.

Refer to FIG. 5 to FIG. 6. FIG. 5 is a schematic structural diagram of plasma treatment. FIG. 6 is a schematic diagram of plasma treatment. Plasma treatment is performed on the surface of the base structure 102 by using a reaction gas. The reaction gas chemically reacts with the adsorption group to cause quantities of precursor adsorption nucleation points on the surface of the base structure 102 to tend to be the same.

After the reaction gas chemically reacts with the adsorption groups, the groups on the surface of the base structure 102 serve as the precursor adsorption nucleation points.

The target layer conformally covering the surface of the base structure 102 is subsequently formed. In some implementations, the plasma treatment is performed on the surface of the base structure 102, so that quantities of the precursor adsorption nucleation on top surfaces and sidewalls of the pattern structures 101 and on the surface of the base layer 100 tend to be same. In this way, the modification to the surface of the base structure 102 is implemented. Since the precursor adsorption nucleation points are used for adsorbing reaction precursors used in the ALD process, a uniform adsorption environment is provided for the reaction precursors. Correspondingly, the thickness uniformity of the target layer is improved, thereby enhancing the performance of a semiconductor.

It is to be noted that, the reaction gas includes O₂, H₂, or a gas containing N and H.

The plasma treatment is performed on the surface of the base structure 102 by using the O₂, H₂, or the gas containing N and H. The O₂, H₂, or the gas containing N and H can chemically react with the adsorption groups, so that the quantities of the precursor adsorption nucleation points on the top surfaces and the sidewalls of the pattern structures 101 and on the surface of the base layer 100 are the same. Therefore, the modification to the surface of the base structure 102 is implemented, and a uniform adsorption environment is provided for the subsequent formation of the target layer.

Specifically, the gas containing N and H includes a gas mixture of N₂ and H₂ or NH₃.

In some implementations, the plasma treatment has a characteristic of high activity. Under a relatively low process temperature environment, the gas easily reacts with the adsorption groups on the surface of the base structure 102, thereby achieving the modification to the surface of the base structure.

In some implementations, the adsorption group on the surface of the base structure 102 is hydroxyl (OH—). A detailed description is given by using an example that the plasma treatment is performed on the surface of the base structure 102 by using O₂.

As shown in FIG. 6, when the plasma treatment is performed on the surface of the base structure 102 by using the O₂, a quantity of hydroxyl (OH—) on the surface of the base structure 102 can be reduced. The hydroxyl (OH—) on the surface of the base structure 102 tends to be saturated when reduced to a certain quantity, so that the quantities of the hydroxyl (OH—) on the surface of the base structure tend to be consistent.

It is to be noted that, in other implementations, the adsorption groups on the surface of the base structure may also be amino. Performing the plasma treatment on the surface of the base structure 102 by using the O₂ can also reduce a quantity of amino.

Thus, the plasma treatment is performed on the top surfaces and the sidewalls of the pattern structures 101 and the surface of the base layer 100 by using the reaction gas O₂, so that the quantities of the precursor adsorption nucleation points on the top surfaces and the sidewalls of the pattern structures 101 and on the surface of the base layer 100 are the same.

In some implementations, the plasma treatment process includes the following parameters: a process duration being in a range of 5 s to 600 s; a chamber pressure being a range of 100 mtorr to 30 torr; a gas flow rate of the reaction gas being in a range of 1 sccm to 90000 sccm; a source radio-frequency power being in a range of 50 W to 2000 W; and a process temperature being in a range of 50° C. to 500° C.

The gas flow rate of the reaction gas should be neither excessively small nor excessively large. If the gas flow rate of the reaction gas is excessively small, the quantity of plasma generated by the reaction gas may be excessively small. Correspondingly, insufficient surface treatment on the base structure 102 is easily caused, and poor uniformity of a treatment effect on the entire base structure 102 is easily caused, which affects the uniformity of the thickness of the subsequently formed target layer. If the gas flow rate of the reaction gas is excessively large, it is easy to cause a waste of process resources and costs. To this end, in some implementations, the gas flow rate of the reaction gas is in a range of 1 sccm to 90000 sccm.

The chamber pressure of the plasma treatment should be neither excessively small nor excessively large. If the chamber pressure of the plasma treatment is excessively small, a vacuum degree in a chamber is higher. Correspondingly, insufficient surface treatment on the base structure 102 is easily caused, resulting in poor uniformity of a treatment effect, and affecting the uniformity of the thickness of the subsequently formed target layer. If the chamber pressure of the plasma treatment is excessively large, the probability of movement and collision of activated gas plasma in the chamber is increased, causing the gas plasma actually reaching the surface of the base structure 102 to be greatly reduced. Correspondingly, the effect of the reaction between the reaction gas and the adsorption groups becomes poor, and the effect of the plasma treatment is reduced. Insufficient surface treatment on the base structure 102 is easily caused, affecting the uniformity of the thickness of the subsequently formed target layer. To this end, in some implementations, the chamber pressure is in a range of 100 mtorr to 30 torr.

Increasing the process temperature facilitates increasing of the rate of dissociation and reaction. When the process temperature is excessively low, the rate of dissociation and reaction is easily caused to be excessively slow, which reduces the efficiency or effect of the plasma treatment. However, when the process temperature is excessively high, adverse effects are easily generated on the performance of the semiconductor structure, and thermal budgets are increased as well. To this end, in some implementations, the process temperature is in a range of 50° C. to 500° C.

An excessively large radio-frequency power may easily cause damage to the surface of the base structure 102. An excessively small radio-frequency power may easily cause a poor effect of the plasma treatment on the surface of the base structure 102. The quantities of precursor adsorption nucleation on the top surfaces and the sidewalls of the pattern structures 101 and on the surface of the base layer 100 differ greatly, causing poor uniformity of the thickness of the subsequently formed target layer, and affecting the semiconductor performance. To this end, in some implementations, the source radio-frequency power is in a range of 50 W to 2000 W.

The duration of the plasma treatment process should be neither excessively short nor excessively long. An excessively short duration of the plasma treatment process may easily cause insufficient surface treatment of the base structure 102, affecting the thickness uniformity of the subsequently formed target layer. An excessively long duration of the plasma treatment process may easily cause damage to the surface of the base structure 102. To this end, in some implementations, the duration of the plasma treatment process is in a range of 5 s to 600 s.

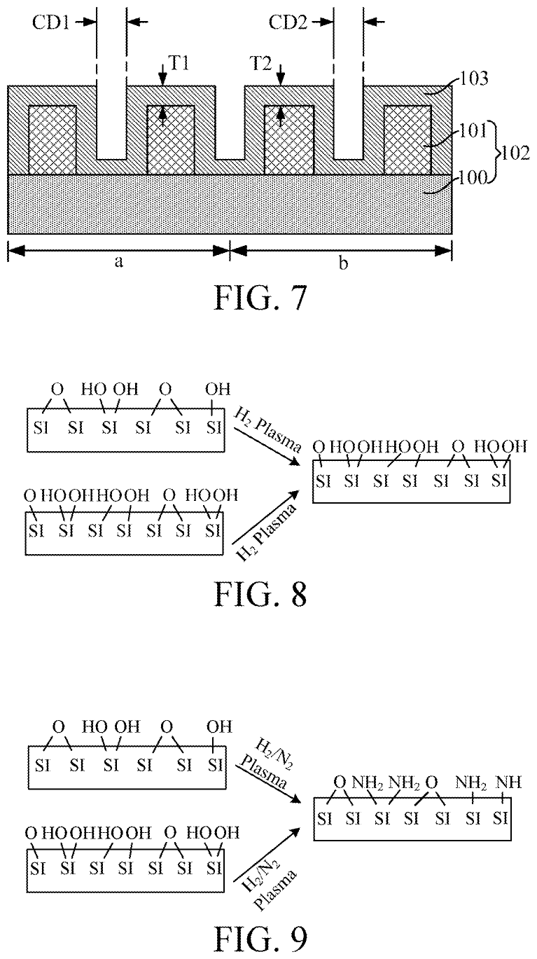

Referring to FIG. 7, after the plasma treatment, a target layer 103 conformally covering the surface of the base structure 102 is formed by using an ALD process.

The target layer 103 provides a process basis for the subsequent manufacturing process.

In some implementations, the target layer 103 is a spacer material layer, and the spacer material layer located on the sidewalls of the pattern structures 101 is used as a spacer. The spacer is configured to protect the sidewalls of the pattern structures 101.

The spacer material layer may be a single-layer structure or a stack structure. Materials of the spacer material layer include one or more of silicon oxide, silicon nitride, silicon carbide, silicon carbonitride, silicon oxycarbonitride, silicon oxynitride, boron nitride, and boron carbonitride.

In some implementations, the material of the target layer 103 includes silicon nitride.

In some implementations, the target layer 103 conformally covering the surface of the base structure 102 is formed using the ALD process.

The ALD process includes a plurality of atomic layer deposition cycles, facilitating the improvement of the thickness uniformity of the target layer 103, so that the target layer 103 can conformally cover the tops and the sidewalls of the pattern structures 101 and the top of the base structure 102. In addition, the ALD process has desirable gap filling performance and step coverage, correspondingly improving the conformal coverage capability of the target layer 103.

Specifically, the ALD process generally provides the ability to deposit a plurality of successive monoatomic layers on the base in the deposition chamber maintained at a negative pressure (a pressure below an atmospheric pressure). The process includes a plurality of deposition sub-steps. The deposition sub-steps include: introducing a first reaction precursor into a deposition chamber, where the first reaction precursor is adsorbed onto a surface of the base; stopping introducing the first reaction precursor into the deposition chamber to cause an inert purge gas to flow through the deposition chamber, so as to remove, from the deposition chamber, the remaining first reaction precursor that is not adsorbed onto the base; introducing a second reaction precursor into the deposition chamber, where the second reaction precursor reacts with the first reaction precursor adsorbed onto the surface of the base; and stopping introducing the second reaction precursor into the deposition chamber to cause the inert purge gas to flow through the deposition chamber, so as to discharge, from the deposition chamber, a by-product formed after the second reaction precursor reacts with the first reaction precursor.

It is to be noted that, the ALD process is a plasma enhanced ALD process.

The plasma enhanced ALD process has a relatively low process temperature, which can reduce the influence on the performance of a semiconductor structure and reduce thermal budgets. In addition, the plasma enhanced ALD process has higher process controllability.

Still referring to FIG. 7, since the quantities of the precursor adsorption nucleation on the top surfaces and the sidewalls of the pattern structures 101 and on the surface of the base layer 100 tend to be the same, during the ALD, a uniform adsorption environment is provided for the surface of the base structure 102, thereby achieving higher thickness uniformity of the target layer 103.

Specifically, the thickness of the target layer 103 formed on the base layer 100 equals the thickness of the target layer 103 formed on the surfaces of the pattern structures.

It is to be noted that, the thickness uniformity of the formed target layer 103 is higher, correspondingly enhancing the performance of the semiconductor structure.

In some implementations, the thickness T1 of the target layer 103 formed on the surfaces of the pattern structures 101 in the first region a equals the thickness T2 of the target layer 103 formed on the surfaces of the pattern structures 101 in the second region b. The thickness of the target layer 103 formed on the surfaces of the pattern structures 101 equals the thickness of the target layer 103 formed on the surface of the base layer 100.

In some implementations, a horizontal distance CD1 between adjacent target layers 103 in the first region is equal to a horizontal distance CD2 between adjacent target layers 103 in the second region b.

A direction perpendicular to an extending direction of the pattern structures 101 is used as a transverse direction. A transverse distance CD1 between the adjacent target layers 103 in the first region is equal to a transverse distance CD2 between the adjacent target layers 103 in the second region b. In this way, the structure arrangement of a semiconductor is optimized, and the structural performance of the semiconductor is enhanced.

It is to be noted that, the implementations described above are described by using an example that the base layer 100 is a substrate, the pattern structure 101 is a gate structure, and the target layer 103 is the spacer material layer. In some other implementations, a to-be-connected structure is formed in the base layer. The pattern structure is a dielectric layer. Adjacent dielectric layers form a conductive opening. The to-be-connected structure is exposed from a bottom of the conductive opening. For example, the to-be-connected structure is a source/drain doped region. The conductive opening is configured to form a conductive plug electrically connected to the to-be-connected structure.

Correspondingly, the target layer is a sidewall protection material layer. The sidewall protection material layer located on the sidewall of the conductive opening is used as a sidewall protection layer, so as to protect the sidewall of the conductive opening.

Correspondingly, by means of the plasma treatment described in some implementations, the thickness uniformity of the sidewall protection material layer is enhanced.

FIG. 8 is a schematic diagram corresponding to another form of a method for forming a semiconductor structure according to the present disclosure.

For the similarity between the form of the present disclosure described below and the form of the present disclosure described above, details are not described herein again. A difference between the present form of the present disclosure and the form of the present disclosure described above lies in that, in the step of performing the plasma treatment on the surface of the base structure, the reaction gas is H₂.

The adsorption group is hydroxyl by way of example. The plasma treatment is performed on the surface of the base structure 102 by using H₂, easily causing an Si—O bond in Si—O—Si on the surface of the base structure to break, so as to form new hydroxyl (OH—). Correspondingly, the quantity of the hydroxyl on the surface of the base structure is increased. The hydroxyl on the surface of the base structure 102 tends to be saturated when increased to a certain quantity, so that the quantities of the precursor adsorption nucleation points on the surface of the base structure tend to be the same.

For specific descriptions of the forming method in the present form of the present disclosure, reference may be made to the corresponding descriptions in the above forms of the present disclosure, as details are not described herein again.

FIG. 9 is a schematic diagram corresponding to yet another form of a method for forming a semiconductor structure according to the present disclosure.

For the similarity between the present form of the present disclosure and the forms of the present disclosure described above, details are not described herein again. A difference between the present form of the present disclosure and the forms of the present disclosure described above lies in that, in the step of performing the plasma treatment on the surface of the base structure, the reaction gas is the gas containing N and H.

The adsorption group is hydroxyl by way of example. The plasma treatment is performed on the surface of the base structure by using the gas containing N and H, easily causing the Si—O bond to break, so as to form new amino (NH— or NH₂). Correspondingly, the quantity (NH— or NH₂) of the amino on the surface of the base structure is increased. The amino (NH— or NH₂) on the surface of the base structure 102 tends to be saturated when increased to a certain quantity. Since the amino is also the precursor adsorption nucleation point facilitating precursor adsorption, the quantities of the precursor adsorption nucleation points on the surface of the base structure tend to be the same.

In some implementations, the gas containing N and H is a gas mixture of N₂ and H₂. In other embodiments, the gas containing N and H may also be NH₃.

For specific descriptions of the forming method in the present form of the present disclosure, reference may be made to the corresponding descriptions in the above forms of the present disclosure, as details are not described herein again.

Although the present disclosure is described above, the present disclosure is not limited thereto. A person skilled in the art can make various changes and modifications without departing from the spirit and the scope of the present disclosure. Therefore, the protection scope of the present disclosure should be subject to the scope defined by the claims.

What is claimed is:

1. A method for forming a semiconductor structure, the method comprising:
providing a to-be-processed base structure, wherein the to-be-processed base structure comprises a base layer and pattern structures protruding from the base layer, and a surface of the base structure has adsorption groups;
performing plasma treatment on the surface of the base structure using a reaction gas, wherein the reaction gas chemically reacts with the adsorption group to cause quantities of precursor adsorption nucleation points on the surface of the base structure to be same; and
after the plasma treatment, forming, using an atomic layer deposition (ALD) process, a target layer conformally covering the surface of the base structure.

2. The method for forming a semiconductor structure according to claim 1, wherein the reaction gas comprises O₂, H₂, or a gas containing N and H.

3. The method for forming a semiconductor structure according to claim 2, wherein the gas containing N and H comprises a gas mixture of N₂ and H₂ or NH₃.

4. The method for forming a semiconductor structure according to claim 1, wherein the adsorption group comprises hydroxyl or amino.

5. The method for forming a semiconductor structure according to claim 1, wherein the pattern structures and the base layer are made of different materials.

6. The method for forming a semiconductor structure according to claim 1, wherein:
the base layer comprises a plurality of regions; and
the pattern structures are respectively located on the base layer in the plurality of regions, wherein concentrations of doped ions in the pattern structures in the plurality of regions are different, or types of doped ions in the pattern structures in the plurality of regions are different, or the pattern structures in the plurality of regions are made of different materials.

7. The method for forming a semiconductor structure according to claim 1, wherein:
the base layer is a substrate, each pattern structure is a gate structure, and the target layer is a spacer material layer; or
a to-be-connected structure is formed in the base layer, the pattern structure is a dielectric layer, adjacent dielectric layers form a conductive opening, the to-be-connected structure is exposed from a bottom of the conductive opening, and the target layer is a sidewall protection material layer.

8. The method for forming a semiconductor structure according to claim 1, wherein the plasma treatment process comprises the following parameters:
the reaction gas being O₂;
a process duration being in a range of 5 s to 600 s;
a chamber pressure being a range of 100 mtorr to 30 torr;
a gas flow rate of the reaction gas being in a range of 1 sccm to 90000 sccm;
a radio-frequency power being in a range of 50 W to 2000 W; and
a process temperature being in a range of 50° C. to 500° C.

9. The method for forming a semiconductor structure according to claim 1, wherein materials of the pattern structures comprise silicon oxide, silicon nitride, or a silicon material.

10. The method for forming a semiconductor structure according to claim 1, wherein a material of the target layer comprises silicon nitride.

11. The method for forming a semiconductor structure according to claim 1, wherein the ALD process comprises a plasma enhanced ALD process.
